(19) United States
(12) Patent Application Publication
(10) Pub. No.: US 2003/0133272 A1
(43) Pub. Date: Jul. 17, 2003

(54) Apparatus and method for facilitating modular frame capacity expansion

(76) Inventors: Robert Braun, Anderson, SC (US); Joseph Greco, Whitehouse Station, NJ (US); Lonnie Spence, Timonium, MD (US)

Correspondence Address: DREIER & BARITZ LLP, 499 PARK AVENUE, 20TH FLOOR, NEW YORK, NY, 10022, US

(21) Appl. No.: 10/197,277

(22) Filed: Jul. 16, 2002

(51) Int. Cl. H05K 5/00

(52) U.S. Cl. 361/730

(57) ABSTRACT

An apparatus and method for facilitating capacity expansion of a modular frame, including a housing associated with the modular frame, wherein the housing contains at least one of wiring, cabling, a connecting device, and equipment, utilized in conjunction with the modular frame, and a mounting device connected to the housing, wherein the mounting device is capable of facilitating a mounting or an attachment of at least one connecting element to the apparatus. The apparatus is capable of being utilized in order to expand the capacity of the modular frame.

### FIELD OF THE INVENTION

The present invention pertains to an apparatus and method for facilitating modular frame capacity expansion and, in particular, to an apparatus and method for facilitating modular frame capacity expansion which provides for the introduction of an additional connecting block or additional connecting blocks to a modular distributing frame and/or housing and/or the introduction of additional connecting blocks to the modular distributing frame or housing environment.

### BACKGROUND OF THE INVENTION

Modular distributing frames or housings are commonly found in telephone central offices and/or in other environments or locations where large numbers of electrical wiring connections are found or utilized. These modular distributing frames or housings typically house numerous wires, connectors, as well as other hardware or circuitry needed and/or utilized in a particular application. For example, modular distributing frames or housings which are utilized in telephone central offices may typically house thousands upon thousands of wires, connectors, jumpers, etc.

As is the case with many other types of electrical equipment or electronic equipment, these modular distributing frames or housings, or the wiring and/or hardware utilized therein, may require maintenance or repair from time to time. In the case of telephone central offices, telephone system expansion efforts can also require service procedures.

The complex nature of, and the amount of, wires, wiring, connectors, termination equipment, jumpers, etc., and other hardware typically found in these modular distributing frames or housings, serves to make maintenance, repair, and/or system expansion, efforts complex, time consuming and very costly. For example, a replacement effort involving a modular distributing frame or housing can involve costs, including the costs associated with engineering and installation supply efforts, which have been known to approach $2.5 million dollars to $10 million dollars and have been known to take from one to three years to complete, depending upon the size of the facility being serviced by the respective modular distributing frame or housing. The effort can also cause disruptions in the operations of the customers for whom the effort is being performed.

Modular distributing frame or housing expansion efforts can typically involve a replacement of the modular distributing frame or housing in its entirety or the expansion of the modular distributing frame or housing if space allows. Expansion efforts can typically involve a transferring of a portion of existing frame terminations to a new line-up in order to make room for tie pairs in order to facilitate connectivity between line-ups. These conventional approaches are undesirable as a replacement of an entire modular distributing frame or housing can be tremendously expensive and cause disruption to a facility. Further, expansion efforts may not always be possible due to space constraints or desirable from a cost standpoint.

### SUMMARY OF THE INVENTION

The present invention pertains to an apparatus and method for facilitating modular frame capacity expansion which overcomes the shortfalls of the prior art. The present invention can provide an apparatus and method for facilitating modular frame capacity expansion which provides for the introduction of an additional connecting block or additional connecting blocks to the modular distributing frame and/or housing and/or the introduction of an additional connecting block or additional connecting blocks to the modular distributing frame and/or housing environment.

The present invention can also provide an apparatus and a method wherein additional connecting blocks can be mounted to and/or attached to a modular distributing frame or housing. The connecting blocks can be mounted at a rear of the modular distributing frame or housing. The connecting blocks can also be mounted at any one or more of a rear of the modular distributing frame or housing, a side of the modular distributing frame or housing, a front of the modular distributing frame or housing, atop the modular distributing frame or housing, and/or underneath the modular distributing frame or housing.

The present invention also provides an apparatus and method wherein any number of connecting blocks can be mounted or attached to the modular distributing frame or housing.

The present invention can be utilized in modular distributing frames or housings which are, or which can be, utilized in telephone central offices, in telephone communication environments, in telecommunication environments, in Internet or networking communication system environments, and/or in any other communication system environments. The present invention can also be utilized in, or in conjunction with, any type or kind of frame or housing which can, or which may, be utilized to house wiring, wiring connections, wiring terminations, and/or associated hardware, in any appropriate application.

The present invention can also be utilized in conjunction with frames or housings employed at or in premises and/or at or in vehicles in order to house wiring and/or wiring connections.

The present invention can also be utilized in conjunction with frames or housings which can be utilized to house any one or more of wires, cables, fiber optic cables, and/or any other conduction and/or connecting medium, regardless of its type, kind, and/or composition.

The present invention can be utilized in conjunction with any type, kind, size, shape, and/or orientation, of frame or housing. The present invention can also be utilized in conjunction with any type, kind, size, and/or shape, of connecting block or connecting blocks.

The apparatus of the present invention can include a housing which can be sized or shaped for the particular application. The housing can also be a modular distributing frame such as those utilized in telephone central offices. The apparatus of the present invention can be utilized in any application or environment in order to house wiring, cabling, wiring connections, wiring terminations, and/or related hardware.

The housing can be manufactured or constructed from any suitable material, such as, for example, metal, metal alloy, plastic, composite, wood, etc., and/or any combination of same. The housing can also include, or can be constructed of, an insulating material and/or a material for preventing and/or reducing interference, such as, but not limited to, electrical interference, electrical field interference, electromagnetic interference, electromagnetic field interference, magnetic interference, magnetic field interference, and/or any other phenomenon which can introduce and/or cause undesirable interference in the housing or housing environment.

The apparatus can also include any number of mounting brackets. The mounting brackets can be mounted to, or attached to, the housing in any appropriate location and by using any appropriate hardware or other techniques or devices. The mounting brackets can contain holes or other means for mounting the various mounting brackets described herein as being utilized in conjunction with the present invention. The mounting brackets can also be manufactured from any suitable material (i.e. metal, metal alloy, plastic, composite, wood, etc.).

The apparatus can also include any number of connecting block mounting bracket(s) which can be mounted to the mounting brackets or to the housing. Any number of the connecting block mounting brackets can be utilized in conjunction with the apparatus of the present invention. The connecting block mounting brackets can be manufactured from any suitable material (i.e. metal, metal alloy, plastic, composite, wood, etc.).

The apparatus can also include one or more connecting blocks. The connecting block(s) can be any suitable device or hardware for facilitating the wiring connections which are facilitated by the apparatus. Any number of connecting blocks can be utilized in conjunction with the apparatus of the present invention.

The connecting block(s) can be mounted to the housing by being mounted to a connecting block mounting bracket by utilizing any appropriate hardware. The connecting block(s) can also be permanently attached to a connecting block mounting bracket.

The connecting block or connecting blocks can be of any suitable type or kind. In this manner, the apparatus of the present invention can be adapted for use with, or can accommodate, different types or kinds of connecting blocks.

The apparatus can also include any number of horizontal jumper fanning ring mounting bracket(s) which can contain any number of horizontal jumper fanning ring(s). The horizontal jumper fanning ring mounting bracket(s) can be manufactured from any suitable material (i.e. metal, metal alloy, plastic, composite, wood, etc.).

The horizontal jumper fanning ring(s) can be utilized in order to serve as a guide for the horizontally oriented wiring extending from the connecting block(s). Any number of horizontal jumper fanning ring(s) can be attached to the horizontal jumper fanning ring mounting bracket(s).

The horizontal jumper fanning ring mounting bracket(s) can be mounted to a mounting bracket(s) by utilizing any appropriate hardware.

The apparatus can also include any number of vertical jumper fanning rings which can be mounted and/or attached to the housing at any appropriate location. The vertical jumper fanning ring(s) can be attached to the housing by utilizing any appropriate hardware and/or mounting bracket(s).

The apparatus can also include a shelf wall and one or more shelf jumper fanning guide(s). The shelf wall can contain a cutout or aperture for facilitating the passing of wiring or cabling from the front of the housing to the rear of the housing. The cutout or aperture can also be utilized in order to facilitate the passing of wiring or cabling from a connecting block or connecting blocks located at the rear of the housing into the interior of the housing. The wall, aperture and jumper fanning guide(s), can be located at any suitable location (i.e. bottom portion, middle portion, side, etc.) on or in the housing.

The apparatus can also include the wiring or cabling which extends from and/or to the connecting block or connecting blocks. The wiring or cabling can extend from the cutout or aperture, through any one or more of a respective shelf wall fanning guides(s), a respective vertical jumper fanning ring(s), a respective horizontal jumper fanning ring(s), and into a respective connecting block or connecting blocks.

A connecting block or group of connecting blocks can be mounted to the housing by being mounted to, or connected or attached to, a respective connecting block mounting bracket. The respective mounting bracket(s) described herein can be selected, oriented, and/or deployed, in any appropriate manner in order to facilitate the mounting of any number of, type of, or configuration of, connecting blocks utilized in conjunction with the present invention. The connecting block or connecting blocks can also be mounted to, or attached to, the housing and/or to any one or more of the various mounting brackets described herein.

The apparatus can be deployed for a typical use. When and if a wiring or cabling expansion effort is desired, a connecting block or group of connecting blocks can be added, or mounted to, the housing and any respective wiring or cabling can be introduced or deployed as needed and/or as desired to effectuate the desired expansion.

The various components of the apparatus of the present invention can be assembled, and the wiring or cabling, can be connected and/or run, in any appropriate order or manner of assembly.

Any of the components of the apparatus of the present invention can be designed and/or configured in order to mount or attach a connecting block or group of connecting blocks any one or more of to the front of the housing, to a side of the housing, to the rear of the housing, atop the housing, and/or underneath the housing.

The present invention can be utilized in order to extend the life of a modular distributing frame, or any other wiring or cabling housing device or equipment, by facilitating the utilization or deployment of an additional connecting block or additional connecting blocks at a rear of, or at any other suitable location on or about an exterior of, a respective modular distributing frame or other wiring or cabling housing device or equipment.

The present invention can be utilized in order to avoid or dispense with the need to effect costly and time consuming wiring or cabling expansion efforts, maintenance efforts, and/or repair efforts. The present invention can also be utilized in order to dispense with the need to add additional wiring or cabling lineups and/or dispense with the need to replace existing modular distributing frames or other wiring or cabling housings or equipment.

The present invention can be utilized to facilitate the capacity expansion of any type of modular distributing frame or any other wiring or cabling housing device or equipment.

### BRIEF DESCRIPTION OF THE DRAWINGS

In the Drawings:

FIG. 1 illustrates a preferred embodiment of the apparatus of the present invention, in a three dimensional perspective view;

FIG. 2 illustrates a front view of the housing of the apparatus of FIG. 1;

FIG. 3 illustrates a front view of the housing of FIG. 2 with connecting blocks attached thereto; and

FIG. 4 illustrates a front view of the apparatus of FIG. 3 with wiring as shown.

### DESCRIPTION OF THE PREFERRED EMBODIMENTS

The present invention pertains to an apparatus and method for facilitating modular frame capacity expansion. In a preferred embodiment, the present invention pertains to an apparatus and method for facilitating modular frame capacity expansion which provides for the introduction of an additional connecting block or additional connecting blocks to the modular distributing frame and/or housing and/or the introduction of an additional connecting block or additional connecting blocks to the modular distributing frame and/or housing environment.

In a preferred embodiment, an additional connecting block or additional connecting blocks can be mounted to and/or attached to a modular distributing frame or housing. In a preferred embodiment, the connecting block or blocks can be mounted or attached at the rear of the modular distributing frame or housing. In another preferred embodiment, the connecting block or blocks can be mounted or attached at any one of more of a rear of the modular distributing frame or housing, a side of the modular distributing frame or housing, a front of the modular distributing frame or housing, atop the modular distributing frame or housing, and/or underneath the modular distributing frame or housing, if space allows.

In another preferred embodiment, any number of connecting blocks can be mounted or attached to the modular distributing frame or housing. In this manner, one or more connecting blocks can be mounted or attached to the modular distributing frame or housing.

In a preferred embodiment, the apparatus and method of the present invention can be utilized in modular distributing frames or housings which are, or can be, utilized in telephone central offices, in telephone communication environments, in telecommunication environments, in Internet and/or networking communication system environments, and/or in any other communication system environments.

In another preferred embodiment, the apparatus and method of the present invention can be utilized in, or in conjunction with, any type or kind of frame or housing which can or which may be utilized to house wiring, wiring connections, wiring terminations, and/or associated hardware, in any appropriate application for such a frame of housing. For example, the apparatus and method of the present invention can also be utilized in conjunction with frames or housings employed at or in premises and/or at or in vehicles in order to house wiring and/or wiring connections.

In another preferred embodiment, the apparatus and method of the present invention can also be utilized in conjunction with frames or housings used to house any one or more of wires, cables, fiber optic cables, and/or any other conduction and/or connecting medium, regardless of its type, kind, and/or composition.

In another preferred embodiment, the apparatus and method of the present invention can be utilized in conjunction with any type, kind, size, shape, and/or orientation, of frame or housing.

In a preferred embodiment, any type, kind, size, and/or shape, of connecting block or connecting blocks can be utilized in conjunction with the apparatus and method of the present invention.

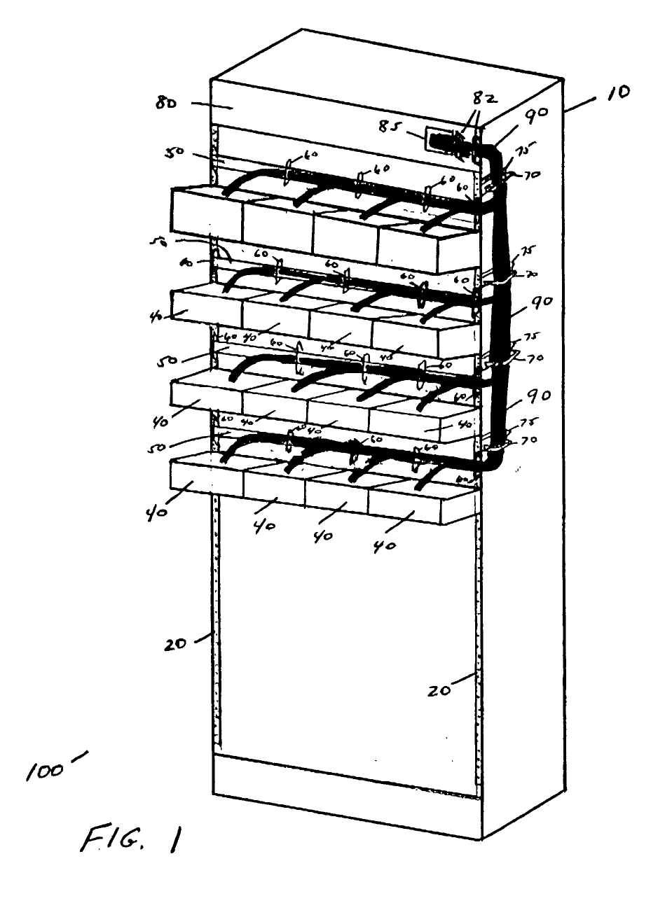

FIG. 1 illustrates a preferred embodiment of the apparatus of the present invention which is designated generally by the reference numeral 100, in a three dimensional perspective view. With reference to FIG. 1, the apparatus 100 includes a housing 10. The housing can be sized or shaped for the particular application.

In a preferred embodiment, the apparatus 100 can be utilized as a modular distributing frame for a telephone central office. It is important to note, however, that the apparatus 100 can also be utilized in any other application or environment in order to house wiring, cabling, wiring connections, wiring terminations, and/or related hardware.

With reference once again to FIG. 1, the housing 10 can be manufactured or constructed from any suitable material, such as, for example, metal, metal alloy, plastic, composite, wood, etc., and/or any combination of same. The housing 10 can also include, or can be constructed of, an insulating material and/or a material for preventing or for reducing interference such as, but not limited to electrical interference, electrical field interference, electromagnetic interference, electromagnetic field interference, magnetic interference, magnetic field interference, and/or any other phenomenon, which can introduce and/or cause undesirable interference in the housing or housing environment.

With reference once again to FIG. 1, the apparatus 100 can include a pair of mounting brackets 20, as shown, which, in the preferred embodiment of FIG. 1, can be attached to the housing 10 at the sides thereof and can extend vertically along a portion of the sides of the housing 10 as shown. In the preferred embodiment, a pair of mounting brackets 20 are utilized. In another preferred embodiment, any number of mounting brackets can be utilized. In another preferred embodiment, the mounting brackets 20 can be attached or mounted to the housing 10 at any location and/or by any suitable manner.

In the preferred embodiment, the mounting brackets 20 can be mounted and/or attached to the housing 10 by utilizing any appropriate hardware, bolts, nuts, etc., and/or can be formed integrally with the housing 10 or components thereof.

In the preferred embodiment, the mounting brackets 20 can contain holes or other means for mounting the various mounting brackets, connecting blocks, fanning rings, etc., described herein as being utilized in conjunction with the apparatus 100 of the present invention. In the preferred embodiment, the mounting brackets 20 can be manufactured from any suitable material (i.e. metal, metal alloy, plastic, composite, wood, etc.).

The apparatus 100 can also include any number of connecting block mounting bracket(s) 30 (not shown). In a preferred embodiment, the connecting block mounting bracket(s) 30 can be mounted to the mounting brackets 20. Any number of connecting block mounting brackets 30 can be utilized in conjunction with the apparatus 100. In the preferred embodiment, the connecting block mounting brackets 30 can be manufactured from any suitable material (i.e. metal, metal alloy, plastic, composite, wood, etc.).

With reference once again to FIG. 1, the apparatus 100 can also include one or more connecting blocks 40. The connecting block(s) 40 can be any suitable device or hardware for facilitating the wiring connections which are provided or facilitated by the apparatus 100. Any number of connecting blocks 40 can be utilized in conjunction with the apparatus 100.

The connecting block(s) 40 can be mounted to, or attached to, the housing 10 by being mounted to the connecting block mounting bracket(s) 30 by utilizing any appropriate hardware. In another preferred embodiment, the connecting block(s) 40 can also be permanently attached to a connecting block mounting bracket 30. The connecting block 40 or connecting blocks 40 can be of any suitable type or kind. In this manner, the apparatus 100 can be adapted for use with, or can accommodate, different types or kinds of connecting blocks 40.

With reference to FIG. 1, the apparatus 100 can also include any number of horizontal jumper fanning ring mounting bracket(s) 50 which can contain any number of horizontal jumper fanning ring(s) 60. In the preferred embodiment, the horizontal jumper fanning ring mounting bracket(s) 50 can be manufactured from any suitable material (i.e. metal, metal alloy, plastic, composite, wood, etc.).

In a preferred embodiment, the horizontal jumper fanning ring(s) 60 can be utilized in order to serve as a guide for the horizontally oriented wiring extending from the connecting block(s) 40, as illustrated in FIG. 1. Any number of horizontal jumper fanning ring(s) 60 can be mounted to, or attached to, a horizontal jumper fanning ring mounting bracket 50.

In a preferred embodiment, a horizontal jumper fanning ring mounting bracket 50 can be mounted to a mounting bracket 20 by utilizing any appropriate hardware.

Any number of horizontal jumper fanning ring mounting brackets 50 can be utilized in conjunction with the apparatus 100. In a preferred embodiment, any number of horizontal jumper fanning ring(s) 60 can also be utilized in conjunction with the apparatus 100.

With reference once again to FIG. 1, the apparatus 100 can also include any number of vertical jumper fanning ring(s) 70 which can be mounted and/or attached to the housing 10 along the sides thereof as shown. In a preferred embodiment, the vertical jumper fanning ring(s) 70, can be mounted on, or attached to, the housing 10 at any location on the housing 10.

In a preferred embodiment, the vertical jumper fanning ring(s) 70 can be attached to the housing 10 by utilizing an associated mounting bracket 75 and any appropriate hardware. The vertical jumper fanning ring(s) 70 can also be mounted to any of the mounting brackets described herein and/or to a mounting bracket dedicated for such use.

With reference once again to FIG. 1, the apparatus 100 can also include a top shelf wall 80 and one or more top shelf jumper fanning guide(s) 82. The top shelf wall 80, in the preferred embodiment, can contain a cutout or aperture 85, which is a hole cut through the top shelf wall, in order to facilitate the passing of wiring or cabling from the front of the housing 10 to the rear of the housing 10. The cutout or aperture 85 can also be utilized in order to facilitate the passing of wiring or cabling from a connecting block 40 or connecting blocks 40 located at the rear of the housing 10 into the interior of the housing 10.

Although described as being located at, or in the vicinity of, the top shelf of the housing 10, a shelf wall 80 and any associated jumper fanning guide 82 or jumper fanning guides 82 can be situated at any location (i.e. bottom portion, middle portion, side, etc.) on or in the housing 10.

With reference once again to FIG. 1, the apparatus 100 can also include wiring or cabling 90 (hereinafter referred to as “wiring 90”) which extends from and/or to a connecting block 40 or connecting blocks 40. As illustrated in the preferred embodiment of FIG. 1, the wiring 90 can extend from the cutout or aperture 85, through one or more of the top shelf fanning guides 82, through one or more of the respective vertical jumper fanning ring(s) 70, through one or more of the horizontal jumper fanning ring(s) 60 and into a respective connecting block 40, as shown. In instances where a wire or cable may have a plurality of terminations, the wire or cable can extend into more than one connecting block 40.

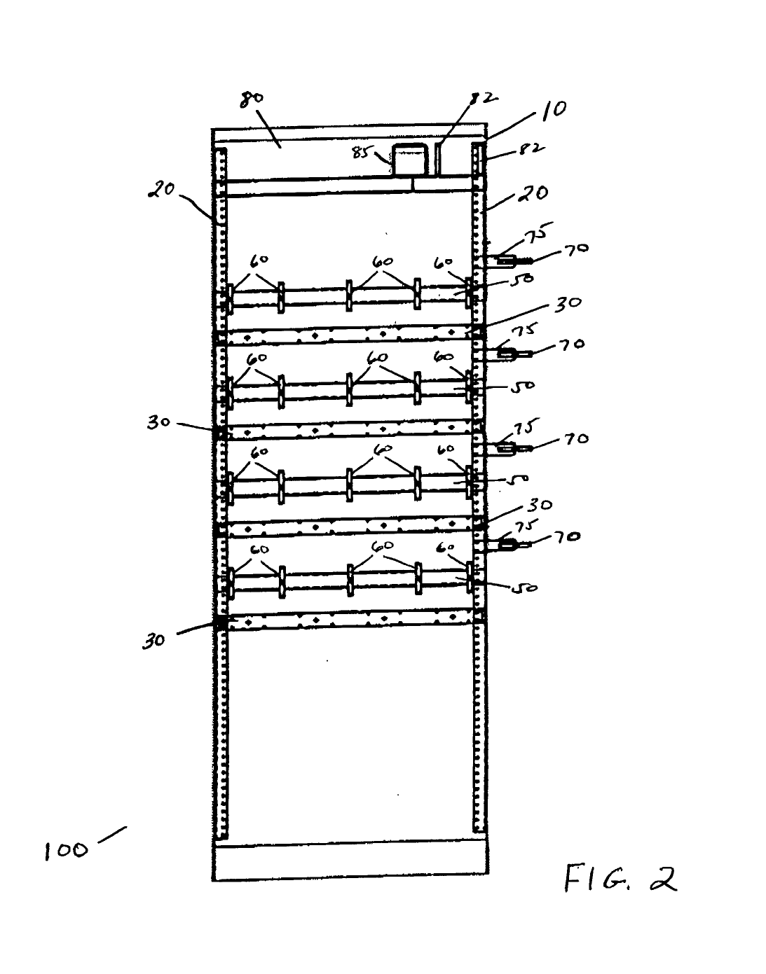

FIG. 2 illustrates a front view of the housing 10 of the apparatus 100 of FIG. 1. The apparatus 100 of FIG. 2 is illustrated without the connecting blocks 40 and the wiring 90. With reference to FIG. 2, the apparatus 100 is shown including the herein described housing 10, the mounting brackets 20, the connecting block mounting brackets 30, the horizontal jumper fanning ring mounting brackets 50 containing a plurality of horizontal jumper fanning rings 60 and the vertical jumper fanning rings 70.

With reference once again to FIG. 2, the apparatus 100 also includes the top shelf wall 80 and the top shelf jumper fanning guides 82. The above-described cutout or aperture 85 in the top shelf wall 80 is also illustrated in FIG. 2. As described herein, the cutout or aperture 85 facilitates the passing of wiring or cabling 90 from the front of the housing 10 to the connecting blocks 40 and/or for facilitating the passing of wiring or cabling 90 from connecting blocks 40 into the interior of the housing 10.

A respective connecting block 40 or group of connecting blocks 40 can be mounted to, or attached to, the housing 10 by being mounted to, or connected or attached to, a respective connecting block mounting bracket 30. As illustrated in FIG. 2, the mounting brackets 20 and the connecting block mounting brackets 30 can be selected, oriented, and/or deployed, in any appropriate manner in order to facilitate the mounting of any number of, type of, or configuration of, connecting blocks 40, which can be utilized in conjunction with the apparatus 100 of the present invention.

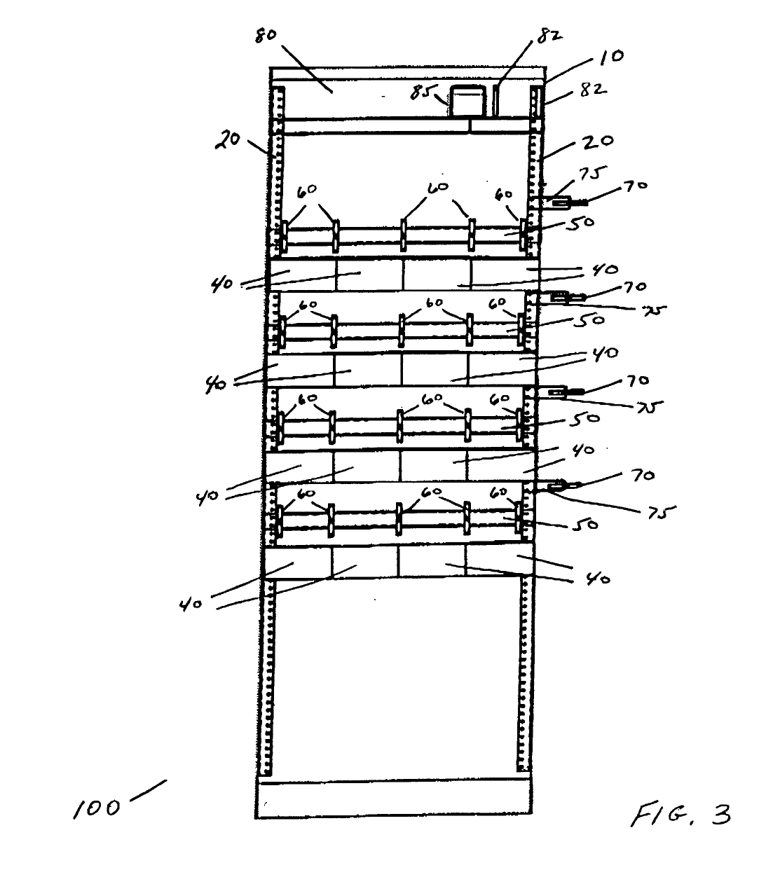

FIG. 3 illustrates a front view of a preferred embodiment of the housing 10 of FIG. 2 shown with a plurality of connecting blocks 40 mounted to, and/or attached to, the housing 10. As described herein, a respective connecting block 40 or connecting blocks 40 can be mounted to a respective connecting block mounting bracket 30 by utilizing any appropriate hardware (i.e. bolts, nuts, connecting or mounting hardware, etc.).

In another preferred embodiment, a connecting block 40 or group of connecting blocks 40 can be mounted to, or attached to, the housing 10 by utilizing any other connecting and/or mounting technique or method, such as, but not limited to, welding, soldering, etc. In another preferred embodiment, the connecting block 40 or connecting blocks 40 can be mounted to, or attached to, the housing 10 and/or to any one or more of the mounting brackets 20, thereby dispensing with the need for utilizing connecting block mounting brackets 30 in such an embodiment.

In the embodiment of FIG. 3, four separate rows of connecting blocks 40 are shown mounted to the housing 10, with each row of connecting blocks 40 containing four connecting blocks 40. It is important to note, however, that any number of rows of connecting blocks 40, containing any number of connecting blocks 40 in each row, can by mounted to, or attached to, the housing 10 and/or can be utilized in conjunction with the apparatus 100.

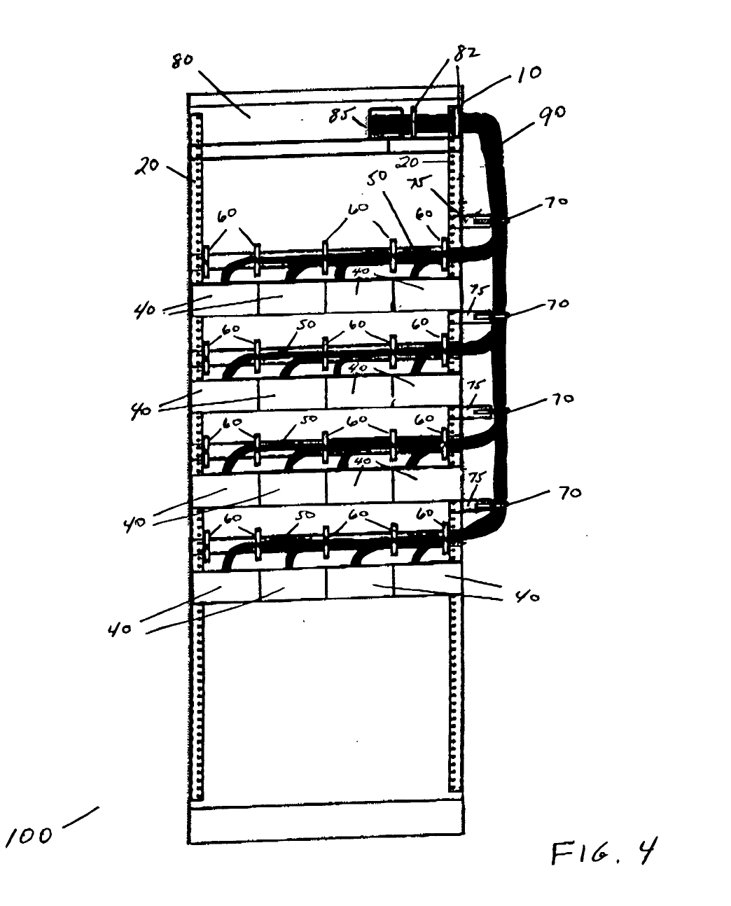

FIG. 4 illustrates a front view of the apparatus 100 of FIG. 3 showing the wiring 90 utilized in conjunction therewith. In the preferred embodiment of FIG. 4, the wiring 90 is shown extending in groups thereof from each of the respective connecting blocks 40, and passing through the respective horizontal jumper fanning rings 60, passing through the respective vertical jumper fanning rings 70, passing through the respective top shelf jumper fanning guides 82, and passing through the cutout or aperture 85 located in the top shelf wall 80.

The apparatus 100 can be deployed for any typical use. When and if a wiring or cabling expansion effort is required and/or desired, a connecting block 40 or group of connecting blocks 40 can be added to the housing 10 and any respective wiring 90 can be introduced or deployed as needed and/or as desired.

The various components of the apparatus 100 of the present invention can be assembled, and the wiring 90 can be connected and/or run, in any appropriate order or manner of assembly.

Although in a preferred embodiment of the apparatus 100 of the present invention, the connecting block 40 or connecting blocks 40 are described and illustrated as being mounted to, or attached to, the rear of the housing 10, it is to be understood that any of the herein-described components of the apparatus 100 can be designed and/or can be configured so as to facilitate the mounting of, or the attachment of, a connecting block 40 or group of connecting blocks 40 at, or to, any one or more of a front side of the housing 100, a side of the housing 100, atop the housing 100, and/or underneath the housing 10, in addition to, and/or instead of, being mounted to or attached to the rear of the housing 10.

The apparatus 100 and method of the present invention serves to extend the life of a modular distributing frame, or any other wiring or cabling housing device or equipment, by facilitating the utilization or deployment of an additional connecting block 40 or additional connecting blocks 40 at a rear of, or at any other suitable location on, at, or about, an exterior of a respective modular distributing frame or any other wiring or cabling housing device or equipment. In this manner, costly and time consuming wiring or cabling expansion efforts, maintenance efforts, and/or repair efforts, can be avoided. The apparatus 100 of the present invention can also be utilized in order to dispense with the need for adding additional wiring or cabling line-ups and/or to dispense with the need to replace existing modular distributing frames or other wiring or cabling housings or equipment.

In the above-described manner, the apparatus 100 and method of the present invention can be utilized in order to facilitate a capacity expansion of any type of modular distributing frame or any other wiring or cabling housing device or equipment.

While the present invention has been described and illustrated in various preferred embodiments, such descriptions are merely illustrative of the present invention and are not to be construed to be limitations thereof. In this regard, the present invention encompasses any and all modifications, variations and/or alternate embodiments with the scope of the present invention being limited only by the claims which follow.

What is claimed is:

1. An apparatus for facilitating capacity expansion of a modular frame, comprising:
a housing associated with the modular frame, wherein the housing contains at least one of wiring, cabling, a connecting device, and equipment, utilized in conjunction with the modular frame; and
a mounting device connected to the housing, wherein the mounting device is capable of facilitating a mounting or an attachment of at least one connecting element to the apparatus,
wherein the apparatus is capable of being utilized in order to expand the capacity of the modular frame.

2. The apparatus of claim 1, wherein the modular frame is a telephone central office modular distribution frame.

3. The apparatus of claim 1, wherein the mounting device is at least one of a mounting bracket and a connecting element mounting bracket.

4. The apparatus of claim 3, wherein the connecting element mounting bracket is mounted to or attached to the mounting bracket.

5. The apparatus of claim 3, wherein at least one connecting element is mounted to the at least one of a mounting bracket and a connecting element mounting bracket.

6. The apparatus of claim 5, wherein the at least one connecting element is mounted at the rear of the housing.

7. The apparatus of claim 5, wherein the at least one connecting element is mounted at the front of the housing.

8. The apparatus of claim 5, wherein the at least one connecting element is mounted at a side of the housing.

9. The apparatus of claim 5, wherein the at least one connecting element is mounted at least one of atop the housing and underneath the housing.

10. The apparatus of claim 1, further comprising:
at least one horizontal jumper fanning ring mounting bracket, wherein the at least one horizontal jumper fanning ring mounting bracket is mounted to or attached to at least one of the housing and the mounting device.

11. The apparatus of claim 10, wherein the at least one horizontal jumper fanning ring mounting bracket further comprises:
at least one horizontal jumper fanning ring.

12. The apparatus of claim 1, further comprising:
at least one vertical jumper fanning ring, wherein the at least one vertical jumper fanning ring is mounted to or attached to the housing via at least one of the mounting device and a vertical jumper fanning ring mounting device.

13. The apparatus of claim 1, further comprising:
a wall section located on or in the housing, wherein the wall section has an aperture therethough for facilitating at least one of a passing of at least one of wiring and cabling from a front of the housing to the rear of the housing and a passing of at least one of wiring and cabling from a rear of the housing into an interior of the housing.

14. The apparatus of claim 13, further comprising:
at least one jumper fanning guide located adjacent the aperture.

15. A method for facilitating capacity expansion of a modular frame, comprising:
mounting at least one connecting element to a housing associated with the modular frame; and
effecting at least one of a wiring connection and a cabling connection between at least one of wiring, cabling, a connecting device, and equipment, located within the housing with at least one of wiring, cabling, a connecting device, and equipment, associated with or at the connecting element.

16. An apparatus for facilitating capacity expansion of a modular frame, comprising:
a housing associated with the modular frame, wherein the housing contains at least one of wiring, cabling, a connecting device, and equipment, utilized in conjunction with the modular frame; and
at least one mounting device connected to the housing; and
at least one connecting element;
wherein the connecting element is mounted to or attached to the housing via the at least one mounting device, wherein the connecting element contains a wiring connection or a cabling connection for expanding the capacity of the modular frame.

17. The apparatus of claim 16, wherein the modular frame is a telephone central office modular distribution frame.

18. The apparatus of claim 16, wherein the mounting device is at least one of a mounting bracket and a connecting element mounting bracket.

19. The apparatus of claim 18, wherein the connecting element mounting bracket is mounted to or attached to the mounting bracket.

20. The apparatus of claim 18, wherein at least one connecting element is mounted to the at least one of a mounting bracket and a connecting element mounting bracket.

21. The apparatus of claim 20, wherein the at least one connecting element is mounted at the rear of the housing.

22. The apparatus of claim 20, wherein the at least one connecting element is mounted at the front of the housing.

23. The apparatus of claim 20, wherein the at least one connecting element is mounted at a side of the housing.

24. The apparatus of claim 20, wherein the at least one connecting element is mounted at least one of atop the housing and underneath the housing.

25. The apparatus of claim 16, further comprising:
at least one horizontal jumper fanning ring mounting bracket, wherein the at least one horizontal jumper fanning ring mounting bracket is mounted to or attached to at least one of the housing and the mounting device.

26. The apparatus of claim 25, wherein the at least one horizontal jumper fanning ring mounting bracket further comprises:
at least one horizontal jumper fanning ring.

27. The apparatus of claim 16, further comprising:
at least one vertical jumper fanning ring, wherein the at least one vertical jumper fanning ring is mounted to or attached to the housing via at least one of the mounting device and a vertical jumper fanning ring mounting device.

28. The apparatus of claim 16, further comprising:
a wall section located on or in the housing, wherein the wall section has an aperture therethough for facilitating at least one of a passing of at least one of wiring and cabling from a front of the housing to the rear of the housing and a passing of at least one of wiring and cabling from a rear of the housing into an interior of the housing.

29. The apparatus of claim 28, further comprising:
at least one jumper fanning guide located adjacent the aperture.
